(19) United States
(12) Patent Application Publication
(10) Pub. No.: US 2010/0020505 A1
(43) Pub. Date: Jan. 28, 2010

(54) Printed Circuit Board Assembly Having Multiple Land Grid Arrays for Providing Power Distribution

(76) Inventors: William L. Brodsky, Binghamton, NY (US); Kevin R. Covi, Glenford, NY (US)

Correspondence Address: IBM CORPORATION;ROCHESTER IP LAW DEPT. 917, 3605 HIGHWAY 52 NORTH, ROCHESTER, MN, 55901-7829, US

(21) Appl. No.: 12/180,700

(22) Filed: Jul. 28, 2008

(51) Int. Cl. H05K 7/20; H05K 1/14

(52) U.S. Cl. 361/721; 361/711; 361/803; 361/709

(57) ABSTRACT

A printed circuit board (PCB) assembly is disclosed. The PCB assembly includes a first PCB, a second PCB and a land grid array (LGA). The first PCB includes signal interconnects for transmitting logic signals and power interconnects for transmitting power signals. In contrast, the second PCB includes only power interconnects for transmitting power signals exclusively. The second PCB also has significantly less vias than the first PCB. The second PCB is connected to the first PCB via the LGA.

### BACKGROUND OF THE INVENTION

1. Technical Field

The present invention relates to printed circuit boards in general, and more particularly, to a printed circuit board assembly having multiple land grid arrays for providing power distribution.

2. Description of Related Art

Generally, printed circuit boards are structures for distributing signals and power to components mounted thereon. Components, such as single-chip modules and multi-chip modules, can be mounted on printed circuit boards via land grid arrays.

Power connections for single-chip modules and multi-chip modules tend to be grouped directly under the modules where the heat dissipation capability is minimal. Meanwhile, the signal contacts tend to be arranged along the perimeters of the modules by using long traces. Having the signal contacts arranged along the perimeter of the modules requires perforations to be added to power planes surrounding the power connections because each signal contact requires a clearance hole (or anti-pad) to be placed in a power plane. Such addition of perforations will increase the resistance of the power planes and subsequently obstructs the current being delivered to the modules. On the other hand, the modules continue to demand more current, and the current requirement may exceed the capability of the power planes.

### SUMMARY OF THE INVENTION

In accordance with a preferred embodiment of the present invention, a printed circuit board (PCB) assembly includes a first PCB, a second PCB and a land grid array (LGA). The first PCB includes signal interconnects for transmitting logic signals and power interconnects for transmitting power signals. In contrast, the second PCB includes only power interconnects for transmitting power signals exclusively. The second PCB also has significantly less vias than the first PCB. The second PCB is connected to the first PCB via the LGA.

All features and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is a cross-sectional diagram of a printed circuit board assembly having multiply land grid arrays for providing power distribution, in accordance with a preferred embodiment of the present invention;

FIG. 2 is a top view of a first land grid array within the printed circuit board assembly from FIG. 1, in accordance with a preferred embodiment of the present invention; and

FIG. 3 is a top view of a second land grid array within the printed circuit board assembly from FIG. 1, in accordance with a preferred embodiment of the present invention.

### DETAILED DESCRIPTION OF A PREFERRED EMBODIMENT

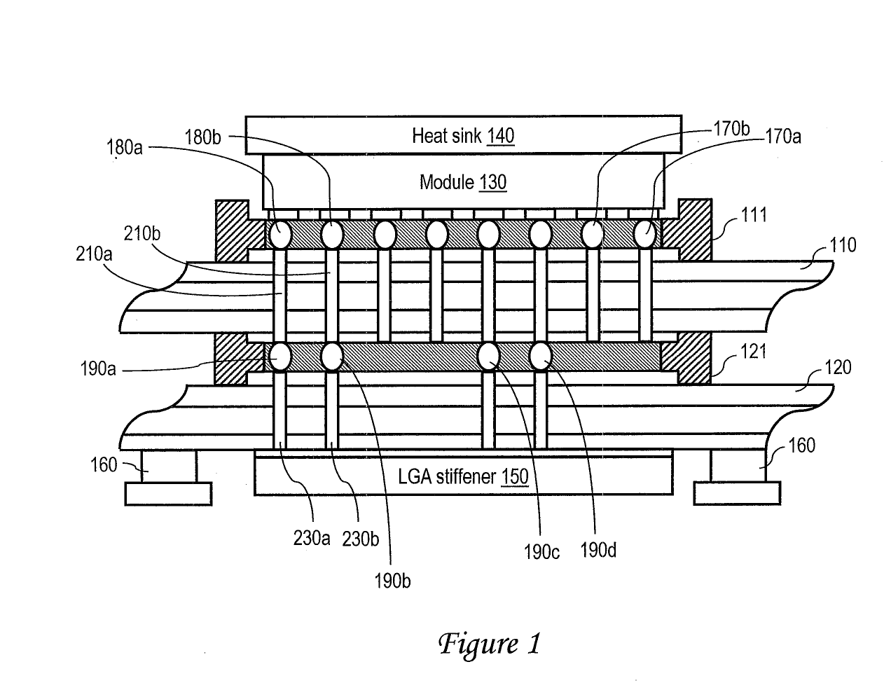

With reference now to the drawings, and in particular to FIG. 1, there is illustrated a cross-sectional diagram of a printed circuit board (PCB) assembly having multiple land grid arrays for providing power distribution, in accordance with a preferred embodiment of the present invention. As shown, a PCB assembly 100 includes a first PCB 110, a second PCB 120, a first land grid array (LGA) 111, and a second LGA 121. First PCB 110 is connected to a module 130 via first LGA 111. Module 130 may be a single-chip module or a multi-chip module having a ceramic substrate. A heat sink 140 is connected to module 130 to provide heat dissipation for module 130. First PCB 110 is connected to second PCB 120 via second LGA 121.

Power regulation circuits 160 can be mounted on second PCB 120 to provide power for module 130. Power regulation circuits 160 include voltage transformation module (VTM) capable of converting a relatively high DC voltage (e.g., 40 V) to a relatively low voltage (e.g., 1V), and multiplying the current where the VTM is remotely located from the voltage regulation portion of the power supply. Thus, power regulation circuits 160 can provide a relatively high current distribution to module 130.

First LGA 111 and second LGA 121 may share an LGA stiffener 150. LGA stiffener 150 may also include a thermal interface for thermal cooling and heat dissipation and an electrical insulator to isolate the plated through holes in PCB 120. In some cases, LGA stiffener 150 may be implemented by using a heat sink or cold plate.

First PCB 110 is similar to second PCB 120 in construction. However, first PCB 110 includes signal interconnects for carrying logic signals as well as power interconnects for carry power signals, and second PCB 120 primarily includes power interconnects to carry current to chip(s) and may include some control circuits for voltage regulation. For example, PCB 110 includes signal interconnects 220a-220b for carrying logic signals as well as power interconnects 210a-210b for carry power signals. In contrast, PCB 120 includes only power interconnects 230a-230b with limited VTM or similar control circuit for carrying chip current. Using two separate PCBs 110 and 120 allows them to be tailored to applications where PCB 110 can have a high percentage of signals leads for high-speed communications, and PCB 120 can have a high percentage of power distribution structure.

As shown in FIG. 1, power to module 130 is supplied by power regulation circuits 160 via power interconnects 210a-210b within PCB 110 and power interconnects 230a-230b within PCB 120. Specifically, power interconnects 210a and 210b within PCB 110 are connected to module 130 via contacts 180a and 180b, respectively. Also, power interconnects 230a and 230b within PCB 120 are connected to power interconnects 210a and 210b within PCB 110 via contacts 190a and 190b, respectively.

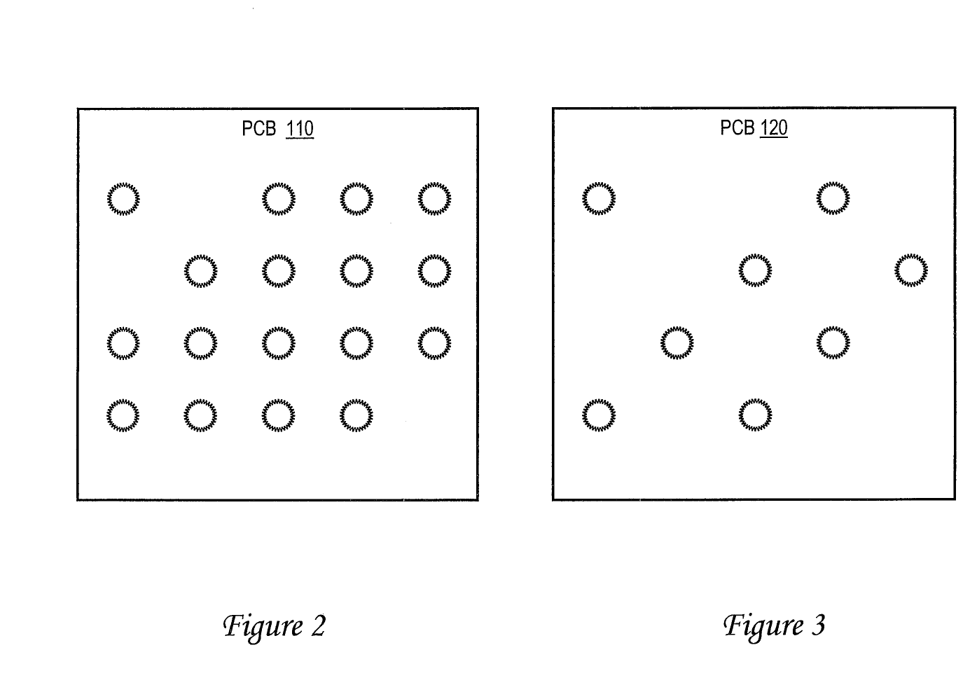

With reference now to FIGS. 2-3, there are illustrated top views of PCB 110 and PCB 120 from FIG. 1, respectively, in accordance with a preferred embodiment of the present invention. As shown, PCB 110 has significantly more contacts or vias than PCB 120, since PCB 120 has only power contacts with limited power control signals, there is substantially more metal or copper structure to carry current and reduce resistive heating.

As has been described, the present invention provides a printed circuit board assembly having multiple land grid arrays for providing power distribution.

While the invention has been particularly shown and described with reference to a preferred embodiment, it will be understood by those skilled in the art that various changes in form and detail may be made therein without departing from the spirit and scope of the invention.

What is claimed is:

1. A printed circuit board (PCB) assembly comprising:
a first PCB having signal interconnects for transmitting logic signals and power interconnects for transmitting power signals;
a first land grid array (LGA); and
a second PCB connected to said first PCB via said first LGA, wherein said second PCB includes only power interconnects for transmitting power signals exclusively, wherein said second PCB has significantly less vias than said first PCB.

2. The PCB assembly of claim 1, wherein said second PCB further includes power regulation circuits to provide power to a module mounted on said first PCB.

3. The PCB assembly of claim 1, wherein PCB assembly further includes a land grid array stiffener for supporting said second PCB.

4. The PCB assembly of claim 3, wherein said land grid array stiffener is a heat sink.

5. The PCB assembly of claim 3, wherein said land grid array stiffener is a cold plate.
